(19) United States
(12) Patent Application Publication
(10) Pub. No.: US 2025/0299934 A1
(43) Pub. Date: Sep. 25, 2025

(54) MAGNETIC FIELD GENERATION DEVICE FOR PLASMA DISTRIBUTION CONTROL AND OPERATING METHOD THEREOF

(71) Applicant: Samsung Electronics Co., Ltd., Suwon-si (KR)

(72) Inventors: Sanghoon JUNG, Suwon-si (KR); Sungyeol KIM, Suwon-si (KR); Kyungsun KIM, Suwon-si (KR); Donghyeon NA, Suwon-si (KR); Jeonghyoun SUNG, Suwon-si (KR); Sungyoung YOON, Suwon-si (KR); Meehyun LIM, Suwon-si (KR); Woongjin CHEON, Suwon-si (KR)

(73) Assignee: Samsung Electronics Co., Ltd., Suwon-si (KR)

(21) Appl. No.: 18/906,522

(22) Filed: Oct. 4, 2024

(30) Foreign Application Priority Data
Mar. 21, 2024 (KR) 10-2024-0039223

(51) Int. Cl. H01J 37/32; H01F 7/06; H01F 7/20

(52) U.S. Cl. CPC H01J 37/32669; H01F 7/064; H01F 7/20; H01J 2237/334

(57) ABSTRACT

Example embodiments are directed a magnetic field generation device including an array of electromagnets including a plurality of electromagnets, and a current controller configured to generate a plurality of current waveforms and to apply each current waveform to a respective one of the plurality of electromagnets. The current controller is further configured to control a pulse duty cycle of each of the plurality of current waveforms. The magnetic field generation device also includes a magnetic field controller configured to calculate each of the plurality of current waveforms to be provided to the respective one of the plurality of electromagnets to generate a desired magnetic field distribution. The plurality of electromagnets include a central electromagnet, and peripheral electromagnets having symmetry in an azimuth direction and arranged about the central electromagnet. Each electromagnet includes a magnetic core and a coil, and a yoke magnetically couples the electromagnets to each other.

### CROSS-REFERENCE TO RELATED APPLICATION

This U.S. non-provisional application claims priority under 35 U.S.C. § 119 to Korean Patent Application No. 10-2024-0039223 filed on Mar. 21, 2024, in the Korean Intellectual Property Office, the disclosure of which is incorporated herein by reference in its entirety.

### BACKGROUND

Example embodiments of the inventive concepts relate to a magnetic field generation device for plasma distribution control and an operating method thereof. Generally, in plasma etching processes, it is necessary to precisely control the plasma to form a desired pattern. For this purpose, time-varying rotating magnetic field generation devices are mainly used. These devices generate a magnetic field that changes over time to control the plasma distribution. The time-varying rotating magnetic field generation device typically generates a rotating magnetic field to make the plasma distribution uniform. This magnetic field rotates the plasma particles, thereby dispersing the plasma uniformly and forming uniform patterns in semiconductor etching. The time-varying rotating magnetic field generation device generates a rotating magnetic field by varying a current flowing therethrough over time. Such devices ensure uniformity and accuracy in plasma processes.

### SUMMARY

Example embodiments of the inventive concepts are directed to a magnetic field generation device configured to control a magnetic field and an operating method thereof.

According to some example embodiments of the inventive concepts, a magnetic field generation device may include an array of electromagnets including a plurality of electromagnets, a current controller configured to generate a plurality of current waveforms and to apply each current waveform to a respective one of the plurality of electromagnets. The current controller is further configured to control a pulse duty cycle of each of the plurality of current waveforms. The magnetic field generation device further includes a magnetic field controller configured to calculate each of the plurality of current waveforms to be provided to the respective one of the plurality of electromagnets to generate a desired magnetic field distribution.

According to some example embodiments, a magnetic field generation device may include a cylindrical yoke, a plurality of magnetic cores on the cylindrical yoke, and a plurality of coils. Each of the plurality of coils is wound around a respective one of the plurality of magnetic cores. Each of the plurality of coils is configured to generate a time-varying rotating magnetic field in response to an applied current waveform.

According to some example embodiments, a magnetic field generation device may include an electromagnet device having a plurality of electromagnets; and a magnetic field sensor layer having a plurality of magnetic sensors, each magnetic sensor corresponding to a position of an electromagnet of the plurality of electromagnets.

According to some example embodiments, a method of operating a magnetic field generation device may include generating a plurality of current waveforms, each of the plurality of current waveforms corresponding to a respective one of a plurality of electromagnets for obtaining a desired magnetic field distribution, and controlling a pulse duty cycle of each of the plurality of current waveforms.

### BRIEF DESCRIPTION OF DRAWINGS

The above and other aspects, features and other advantages of the example embodiments will be more clearly understood from the following detailed description, taken in conjunction with the accompanying drawings.

FIGS. 1A and 1B illustrate a plasma distribution control of an existing magnetic field generation device.

FIG. 2 illustrates center-edge E/R imbalance due to harmonic components.

FIG. 3 is a graph illustrating that uniformity may be controlled by a magnetic field.

FIG. 4 illustrates a magnetic field generation device, according to some example embodiment.

FIGS. 5A and 5B illustrate a structure of an electromagnet array according to some example embodiments.

FIGS. 6A and 6B illustrate a structure of an electromagnet array, according to another example embodiment of the inventive concepts.

FIGS. 7A and 7B illustrate an operation of the current controller of FIG. 4, according to some example embodiment.

FIGS. 8A, 8B, and 8C illustrate output waveforms according to control signals of the current controller of FIG. 4, according to some example embodiment.

FIGS. 9A, 9B, and 9C illustrate current waveforms obtained by varying the pulse duty cycle.

FIG. 10 illustrates an operation of the magnetic field generation device, according to some example embodiment.

FIGS. 11A and 11B illustrate a variation in intensity of magnetic flux density due to the electromagnets EM in the absence and presence of a yoke.

FIGS. 12A, 12B, and 12C illustrate changes in magnetic field distribution according to a direction and magnitude of current in each peripheral electromagnet and the central electromagnet of FIG. 4.

FIG. 13 illustrates magnetic field distribution control via temporal current control in a magnetic field generation device, according to some example embodiment.

FIGS. 14A, 14B, and 14C illustrate uniformity in an azimuth direction according to a phase difference of each electromagnet of a magnetic field generation device, according to some example embodiment.

FIG. 15 is a flowchart of an operation of a magnetic field generation device of FIG. 4, according to some example embodiment.

FIG. 16 illustrates a semiconductor wafer processing system for performing plasma etching on a semiconductor wafer, according to some example embodiment.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Example embodiments disclose a time-varying rotating magnetic field generation device and an operating method thereof for plasma distribution control. The magnetic field generation device and the operating method may control the radial and azimuthal direction uniformity of the etching equipment by generating a time-varying rotating magnetic field by controlling the temporal current waveform of each individual electromagnet array. The magnetic field generation device and the operating method enable temporal distribution control, azimuthal direction uniformity control, and the generation of azimuthal direction magnetic fields.

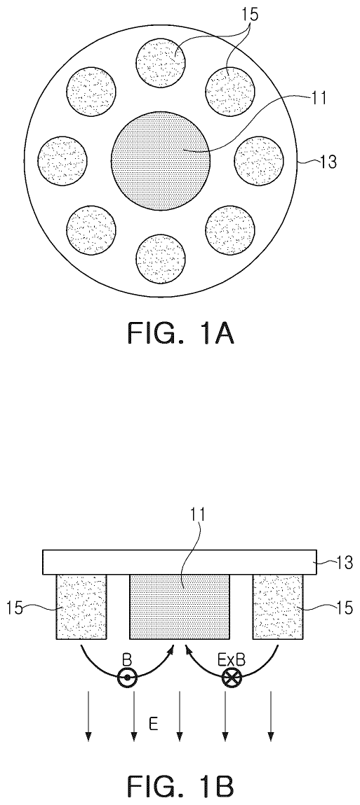

FIGS. 1A and 1B illustrate a plasma distribution control of an existing magnetic field generation device. As illustrated in FIG. 1A, the magnetic field generation device includes a central electromagnet 11 in a central portion of a yoke 13 and edge electromagnets 15 surrounding (e.g., circumferentially) the central electromagnet 11. As illustrated in FIG. 1B, electron density increases due to an E×B drift phenomenon of a magnetic field (B) and an electric field (E). Accordingly, plasma distribution control may be performed. Existing PVD (Physical Vapor Deposition) facilities use an E×B drift effect caused by this magnetic field. Recently, application to an etching facility has also been expanding.

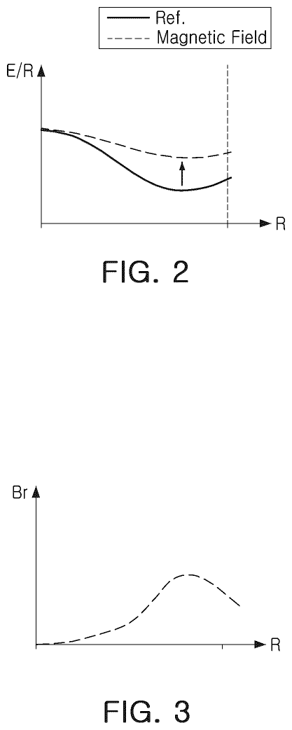

FIG. 2 illustrates center-edge E/R imbalance due to harmonic components. A permanent magnet or electromagnet is used to generate a magnetic field. An electromagnet may control a polarity/magnitude of the magnetic field.

FIG. 3 is a graph illustrating that uniformity may be controlled by a magnetic field. In an etching facility, a magnetic field generated using electromagnets may be controlled in a radial direction. It is difficult to control a magnetic field profile and dispersion in an azimuth direction depending on a structure of the electromagnet array. Existing magnetic field generation devices do not have a compensation technique for the hysteresis characteristics of the magnetic core, and it is difficult to generate a magnetic field in the azimuth direction.

The magnetic field generation device, according to an example embodiment, may form various magnetic field profiles by generating a time-varying rotating magnetic field using an electromagnet. As a result, the magnetic field generation device, according to some example embodiments, may control uniformity in the radial and azimuth directions. The magnetic field generation device may control plasma density by E×B drift of a magnetic field (B) and an electric field (E). The magnetic field generation device may control uniformity in an etching facility and an erosion profile in a PVD facility by controlling plasma density by controlling a magnetic field. The magnetic field generation device may form various magnetic field distributions with magnetic fields varying in time and space. As a result, the magnetic field generation device may control plasma distribution using a magnetic field that may be controlled in time and space.

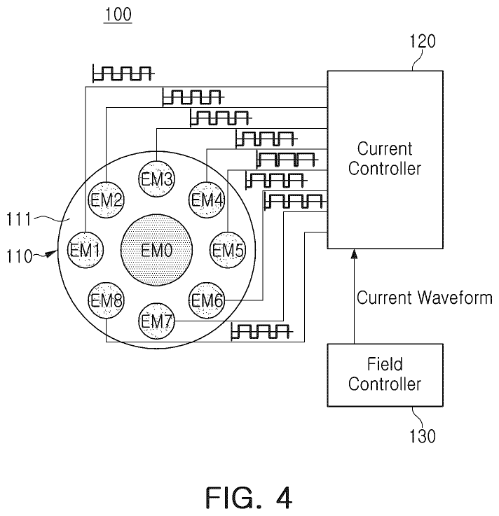

FIG. 4 illustrates a magnetic field generation device 100, according to an example embodiment. Referring to FIG. 4, the magnetic field generation device 100 may include an electromagnet device 110, a current controller 120, and a magnetic field controller 130.

The electromagnet device 110 may include a central electromagnet EM0 and electromagnets EM1 to EM8 (also referred to as peripheral electromagnets EM1 to EM8) surrounding the central electromagnet EM0. For the purposes of discussion herein, the central electromagnet EM0 and electromagnets EM1 to EM8 may be collectively referred to as electromagnets EM. In an example, and as illustrated, the electromagnets EM1 to EM8 may be arranged circumferentially about the central electromagnet EM0 at equal radial distances from the central electromagnet EM. However, example embodiments are not limited thereto, and in other example embodiments, the number of electromagnets EM1 to EM8 and their arrangement about the central electromagnet EM0 may be varied. For instance, the number of electromagnets may be less than 8 or more than 8, and/or the number of electromagnets may be arranged at different radial distances from the central electromagnet EM0. In some example embodiments, the electromagnet array is an array of electromagnets made of a magnetic core and each electromagnet of the array may generate a magnetic field by receiving a current from a current controller. In an example, and as illustrated, the central electromagnet EM0 and the electromagnets EM1 to EM8 may form an electromagnet array. In some example embodiments, the electromagnets EM1 to EM8 may be disposed to have symmetry in an azimuth direction.

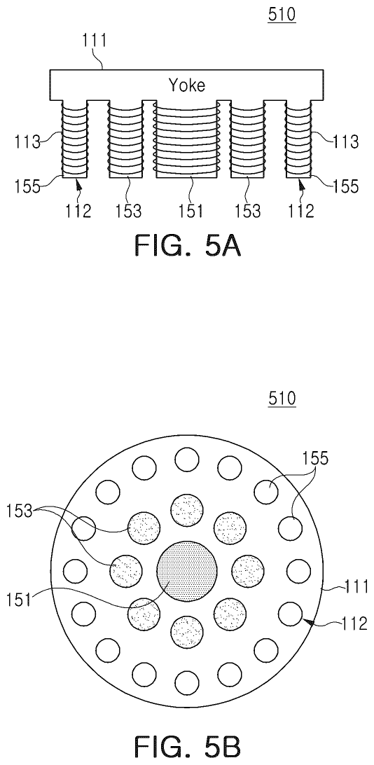

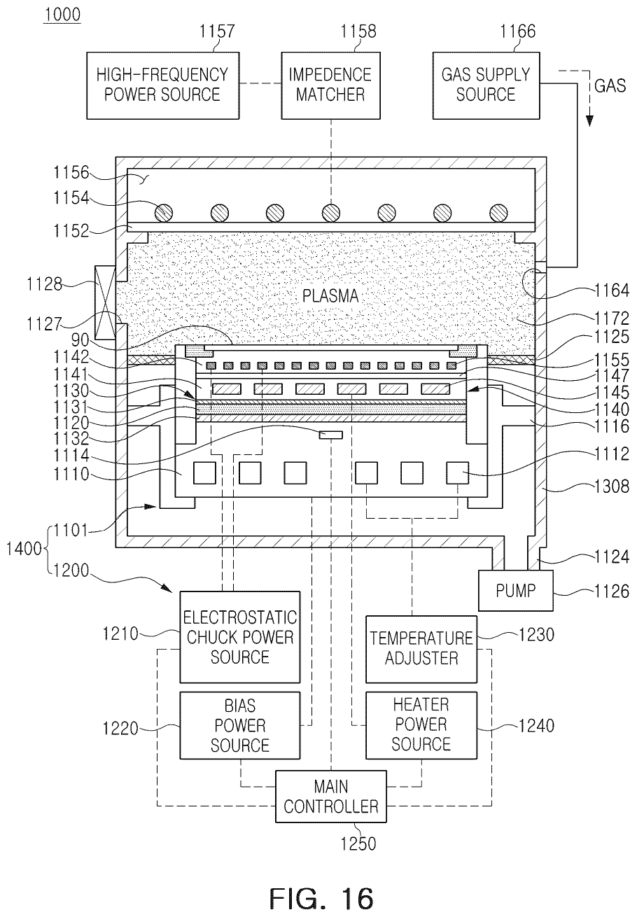

The electromagnet device 110 may include a magnetic yoke 111 and an electromagnet array, which includes electromagnets having a magnetic core (e.g., a core 112 as in FIGS. 5A and 5B) and respective coils (e.g., a coil 113 as in FIG. 5A). The electromagnetic device 110 may be configured to increase magnetic flux density inside a process chamber (e.g., process chamber 1308 in FIG. 16) of a plasma etching device (e.g., plasma etching device 1000). The electromagnets of the electromagnetic array are magnetically coupled to each other via the magnetic yoke 111. In some example embodiments, the magnetic core and magnetic yoke 111 may be integrally implemented. For instance, the magnetic core and magnetic yoke 111 may form a single, unitary structure, as opposed to the magnetic core and magnetic yoke 111 being separate structures that are coupled (attached) to each other. In some example embodiments, an electromagnet device with higher magnetic flux density from an edge to a center may be used to match the total amount of flux generated by the electromagnet device. In some example embodiments, the electromagnet device 110 may include an electromagnet array having symmetry in the azimuth direction. Embodiments of the electromagnet device 110 are not limited to the embodiments disclosed herein and the electromagnet device 110 may include various electromagnet array structures and configurations, as required by application and design.

The current controller 120 may be configured to perform pulse duty control based on a current waveform command provided by the magnetic field controller 130 and output a corresponding current waveform by controlling (or, otherwise varying) the pulse duty cycle. In other words, the current controller 120 may supply the corresponding current to the corresponding electromagnets EM1 to EM8 by calculating the pulse duty cycle. In some example embodiments, each current waveform output from the current controller 120 may have the same pulse duty cycle. In other embodiments, at least one current waveform output from the current controller 120 may have a different pulse duty cycle from at least one other current waveform output from the current controller 120.

The magnetic field controller 130 may be configured to calculate a temporal current waveform to be provided to each electromagnet to generate a desired magnetic field (or, a target magnetic field) distribution and transmit a current waveform command corresponding to each current waveform to the current controller 120. In some example embodiments, the current waveform has magnitude and phase ((A₁,Φ₁), . . . , (A_{N}, Φ_{N})) over time.

The magnetic field generation device 100 may be embedded in a showerhead (used to distribute reactant gas) located in an upper portion of the chamber (e.g., the process chamber 1308 in FIG. 16) of a plasma etching device (e.g., plasma etching device 1000). In another example embodiment, the magnetic field generation device 100 may be mounted on a sidewall of the chamber.

In some example embodiments, the magnetic field generation device 100 may include an integrated core and yoke structure to increase the magnetic flux density inside the chamber (e.g., process chamber 1308 in FIG. 16).

FIGS. 5A and 5B illustrate a structure of an electromagnet array according to some example embodiments. FIG. 5A illustrates a side view of the electromagnet device 510, and FIG. 5B illustrates a bottom view of the electromagnet device 510.

As illustrated in FIG. 5A, the electromagnet device 510 may be implemented integrally with a cylindrical yoke 111 and a plurality of cylindrical cores 112. Coils 113, with multiple turns, are wound around each core 112, respectively. In an alternative embodiment, two or more coils may be electrically connected (e.g., a single wire forming multiple coils). As illustrated in FIG. 5B, the plurality of cylindrical cores 112 may include a central core 151, first cores 153 surrounding (e.g., circumferentially) the central core 151, and second cores 155 surrounding (e.g., circumferentially) the first cores 153. Each first core 153 may be located at a same radial distance from the central core 151 (or, otherwise, from the center of the yoke 111). Each second core 155 may be located at a same radial distance from the central core 151 (or, otherwise, from the center of the yoke 111), with the second cores 155 radially farther from the central core 151 than the first cores 153. In some example embodiments, the first cores 153 and the second cores 155 have symmetry in the azimuth direction. In some example embodiments, a cross-sectional area of the central core 151 may be larger than a cross-sectional area of each of the first cores 153, and the cross-sectional area of each of the first cores 153 may be larger than a cross-sectional area of each of the second cores 155.

In some example embodiments, in order to limit distortion of magnetic field distribution due to leakage of magnetic flux, an electromagnet with a higher degree of magnetic flux density from an edge to a center may be used to adjust the total amount of magnetic flux generated by the electromagnet. In some example embodiments, the electromagnet may be manufactured with 400 coil turns and an allowable current of 3 A for current response characteristics for temporal control.

The magnetic field generation device, according to some example embodiments may include a magnetic field sensor layer for compensation considering the hysteresis characteristics of the magnetic core.

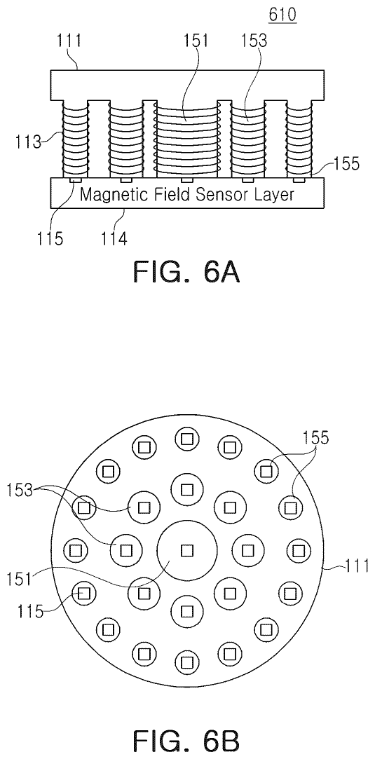

FIGS. 6A and 6B illustrate a structure of an electromagnet array, according to some example embodiments. FIG. 6A illustrates a side view of an electromagnet device 610, and FIG. 6B illustrates a bottom view of the electromagnet device 610. The electromagnet device 610 may be the same in some respects to the electromagnet device 510 of FIGS. 5A and 5B, and therefore may be best understood with reference thereto where like numerals indicate like elements not described again in detail. As illustrated in FIG. 6A, the electromagnet device 610 may further include at least one magnetic field sensor for compensation of magnetic flux density. For example, the electromagnet device 610 may include a magnetic field sensor layer 114 in a lower portion thereof opposite the yoke 111. The magnetic field sensor layer 114 may measure magnetic fields at about 3000 G, and may include a plurality of magnetic sensors 115 each corresponding to a position of the central core 151, the first cores 153, and the second cores 155.

The magnetic field generation device 100, according to some example embodiments, may generate target magnetic field distribution by a time-varying rotating magnetic field. For example, the magnetic field generation device 100 may form a magnetic field in radial/azimuth directions and a local magnetic field by controlling each electromagnet. In addition, the magnetic field generation device 100 may generate a magnetic field in the azimuth direction.

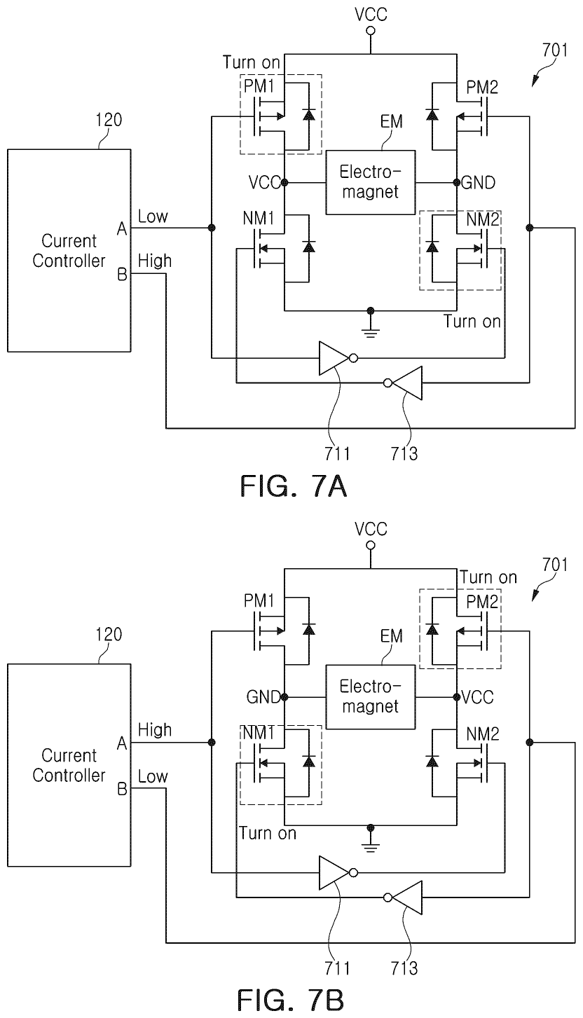

FIGS. 7A and 7B illustrate an operation of the current controller 120, according to some example embodiments. The current controller 120 will be described with respect to a single electromagnet EM, but it will be understood that the structure of FIGS. 7A and 7B are respectively provided for each electromagnet. Referring to FIGS. 7A and 7B, the current controller 120 may be connected to an H-bridge (half-bridge) circuit 701 that is configured to apply a current waveform to an electromagnet EM. Here, an output of the H-bridge circuit may be connected to one end of each electromagnet.

The H-bridge circuit 701 may include P-channel transistor transistors PM1, PM2, N-channel transistors NM1, NM2, and inverters 711 and 713.

The first P-channel transistor PM1 is connected between a power supply voltage VCC and one end of the electromagnet EM, and has a gate connected to a first output terminal A of the current controller 120. The second P-channel transistor PM2 is connected between the power supply voltage VCC and the other end of the electromagnet EM, and has a gate connected to a second output terminal B of the current controller 120. Here, complementary voltages may be applied as voltages of the first output terminal A and the second output terminal B. For example, as illustrated in FIG. 7A, when a low voltage is applied to the first output terminal A, a high voltage may be applied to the second output terminal B. In addition, as illustrated in FIG. 7B, when a high voltage is applied to the first output terminal A, a low voltage may be applied to the second output terminal B. The first N-channel transistor NM1 is connected between one end of the electromagnet and a ground voltage GND, and has a gate connected to the inverter 713 that inverts the voltage of the second output terminal B of the current controller 120. The second N-channel transistor NM2 is connected between the other end of the electromagnet EM and the ground voltage GND, and has a gate connected to the inverter 711 that inverts the voltage of the first output terminal A of the current controller 120. In an embodiment, each of the transistors PM1, PM2, NM1, and NM2 may be implemented as a power semiconductor transistor.

In addition, the current controller 120 may receive a target current waveform from the magnetic field controller 130, for instance, via a communication cable connected thereto. In some example embodiments, the current controller 120 may be implemented to supply current to form an arbitrary current waveform. In some example embodiments, the current controller 120 may be implemented as a microcontroller unit MCU including communication, calculation, and Pulse Width Modulation (PWM) functions. In some example embodiments, the current controller 120 may be implemented as an H-bridge circuit capable of applying a current of 3 A to the electromagnet EM. In some example embodiments, when a magnetic field sensor layer 114 is provided, the current controller 120 may perform feedback control with a magnetic sensor (e.g., magnetic sensor 115 in FIG. 6B).

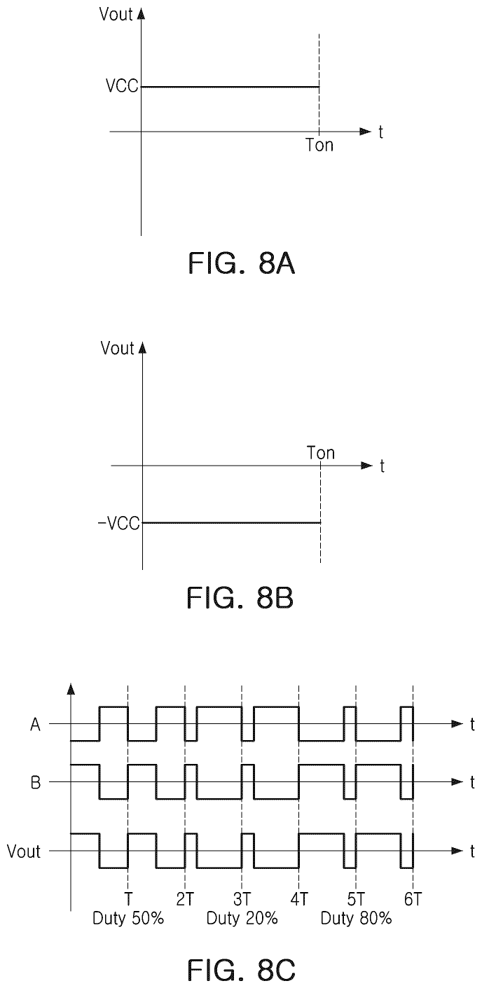

FIGS. 8A, 8B, and 8C illustrate output waveforms according to control signals of a current controller 120, according to some example embodiments. The current controller 120 may supply a desired current waveform to the corresponding electromagnet EM. As illustrated in FIGS. 8A and 8B, the current controller 120 may supply bidirectional current that may change polarity of an electromagnet EM. In some example embodiments, the current controller 120 may individually control the electromagnet current applied to an electromagnet EM of the electromagnet array. As illustrated in FIG. 8C, the current controller 120 may form an output waveform of the applied current by temporally varying pulse duty of control signals A and B applied at the respective output terminals A and B. For example, a time-varying current waveform may be formed based on the duty ratio.

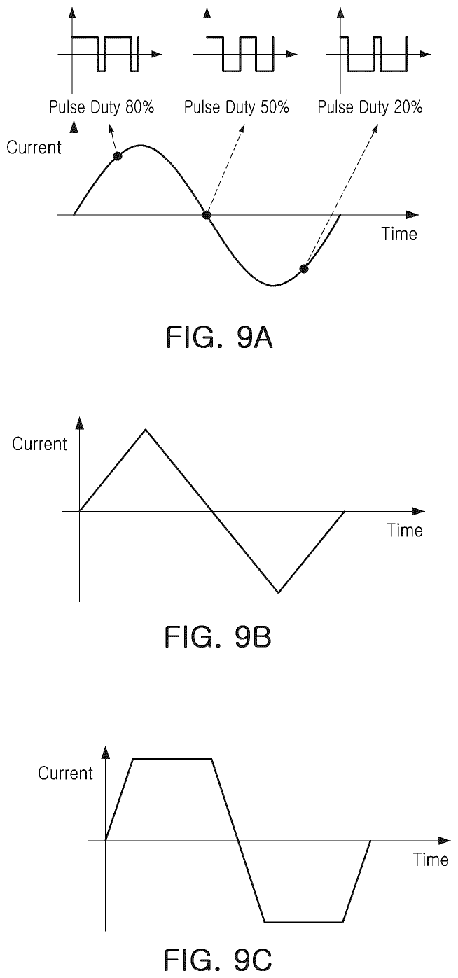

By varying the pulse duty cycle, the current controller 120, according to embodiments of the inventive concepts, may generate different current waveforms. FIGS. 9A, 9B, and 9C illustrate current waveforms obtained by varying the pulse duty cycle.

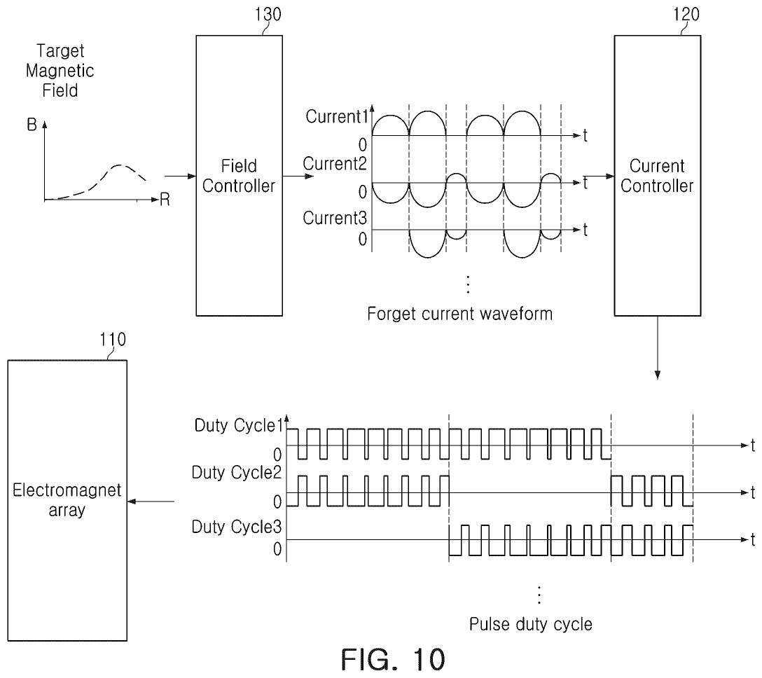

FIG. 10 illustrates an operation of the magnetic field generation device 100, according to some example embodiments. In example embodiments, the magnetic field generation device 100 may be a time-varying rotating magnetic field generation device 100. The magnetic field controller 130 may generate a current waveform command corresponding to a target magnetic field for each electromagnet EM to control the magnetic field distribution. The magnetic field controller 130 may calculate a current waveform forming a desired magnetic field distribution, and transmit a command corresponding to the calculated current waveform to the current controller 120.

In some example embodiments, the magnetic field controller 130 may calculate a magnitude and phase of a current waveform to be applied to each electromagnet EM to generate a rotating magnetic field according to the target magnetic field distribution. In some example embodiments, the magnetic field controller 130 may be implemented as a processor capable of mounting an optimization algorithm for deriving the target magnetic field distribution. In some example embodiments, the magnetic field controller 130 may be communicatively coupled to the current controller 120 and transmit a command corresponding to the current waveforms to the current controller 120.

The current controller 120 may control the current waveform provided to each electromagnet by controlling the pulse duty according to the current waveform command. As a result, a time-varying rotating magnetic field may be formed in the electromagnet device 110 (or electromagnetic devices 510, 610) including an electromagnet array of electromagnets EM.

In some example embodiments, a plurality of electromagnets EM may be disposed to have symmetry in an azimuth direction. In some example embodiments, at least one magnetic sensor 115 may sense a magnetic field of each of the plurality of electromagnets EM. In some example embodiments, one or more current waveforms may be corrected according to the sensed magnetic field. In some example embodiments, polarities of the plurality of electromagnets may be varied by controlling a pulse duty cycle.

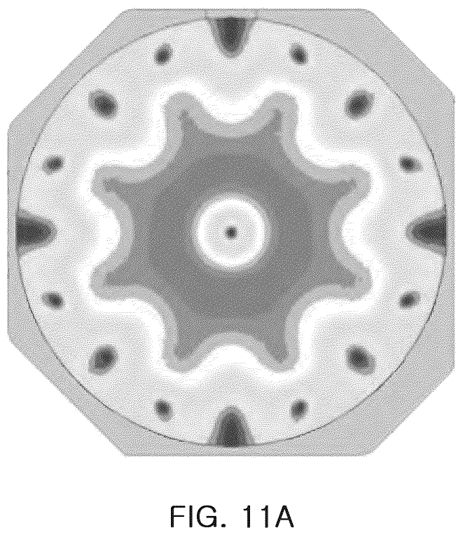

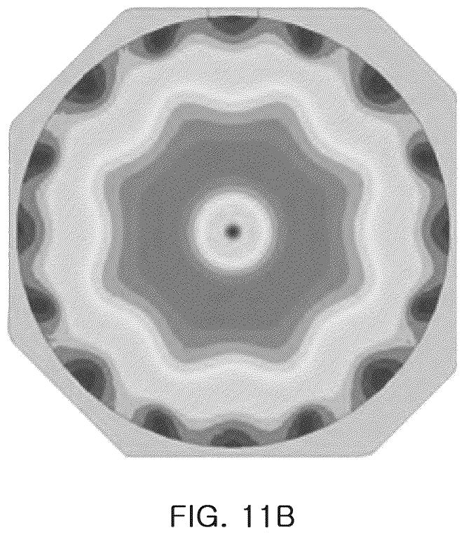

FIGS. 11A and 11B illustrate a variation in intensity of magnetic flux density due to the electromagnets EM in the absence and presence of a yoke. FIG. 11A illustrates magnetic flux density in the absence of a yoke, and FIG. 11B illustrates magnetic flux density in the presence of a yoke. As seen, the magnetic flux density is greater in the presence of the yoke compared to in the absence of the yoke.

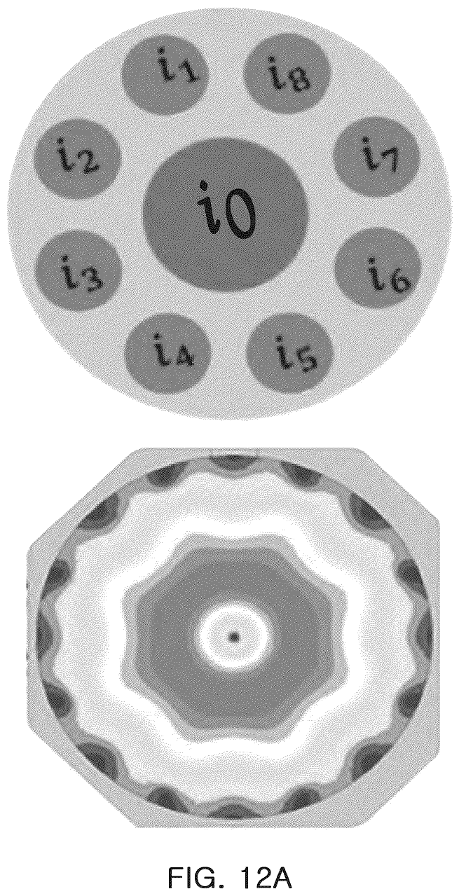

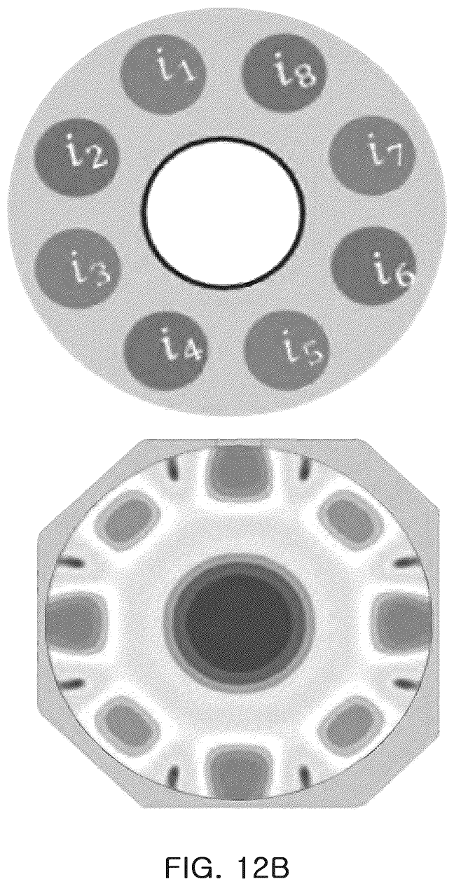

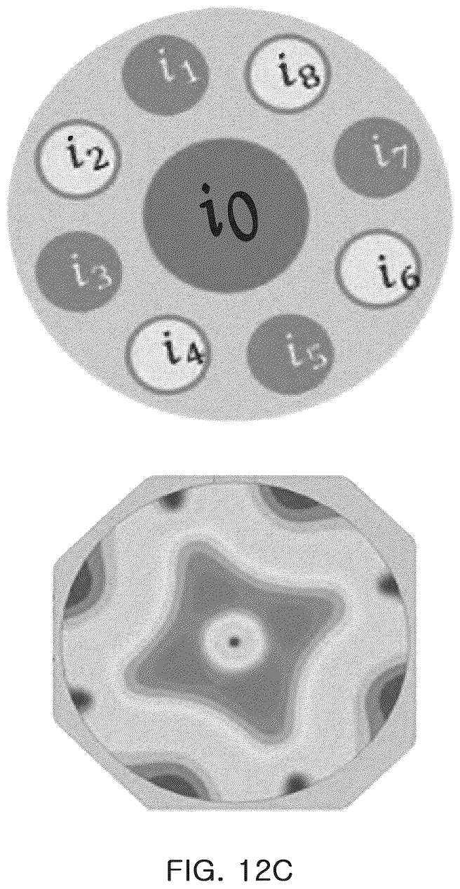

FIGS. 12A, 12B, and 12C illustrate changes in magnetic field distribution according to a direction and magnitude of current in each electromagnet EM1-EM8 and the central electromagnet EM0 in FIG. 4. In FIGS. 12A-12C, current i0 flows through the central electromagnet EM0 and currents i1-18 flowing in the electromagnets EM1-EM8, respectively. FIG. 12A illustrates a magnetic field in a radial direction, FIG. 12B illustrates a magnetic field in an azimuth direction, and FIG. 12C illustrates a local magnetic field. In FIG. 12A currents i0 and i1-i8 flow through all respective electromagnets EM. In FIG. 12B, current i0 does not flow through the central electromagnet EM0, while currents i1-i8 flow through the electromagnets EM1-EM8. In FIG. 12C, currents i0, i1, i3, i5, and i7 flow through the central electromagnet EM0, and electromagnets EM1, EM3, EM5, and EM8, respectively, and currents i2, i4, and i8 do not flow.

The magnetic field generation device, according to some example embodiments, has magnetic field distribution appearing as a time average affecting plasma distribution using a time-varying rotating magnetic field, and enables the formation of various magnetic field profiles as illustrated in FIGS. 12A-12C. Such magnetic field profiles cannot be formed using existing electromagnet array structures. The magnetic field generation device, according to some example embodiments, may solve dispersion in the azimuth direction due to electromagnet spacing through time-varying control using a phase difference of each electromagnet. As a result, the magnetic field generation device of the inventive concepts may provide uniformity in the azimuth direction by optimal phase difference.

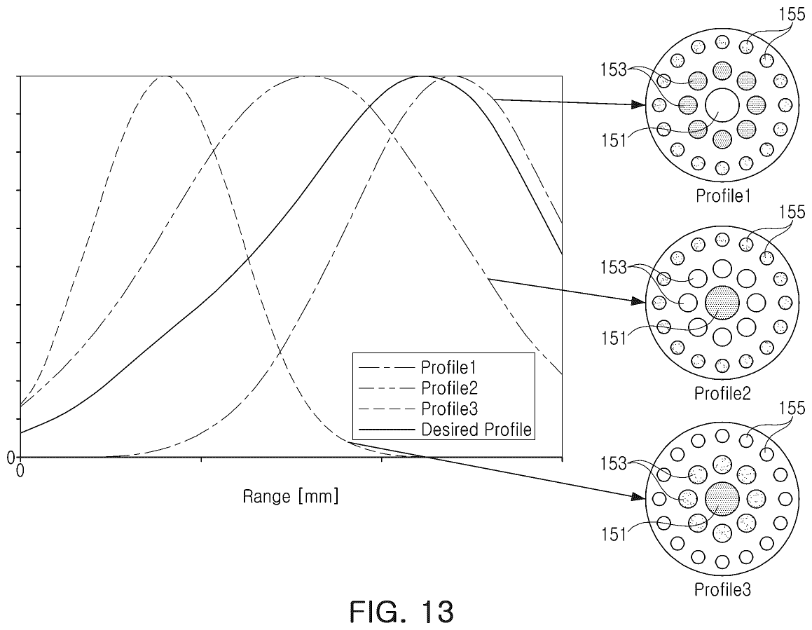

FIG. 13 illustrates magnetic field distribution control via temporal current control in a magnetic field generation device, according to some example embodiments. As illustrated, different magnetic field distribution profiles may be obtained by varying currents flowing through the central core 151, first cores 153, and second cores 155 in FIGS. 5A-5B and 6A-6B. Profile 1 is obtained when current flows through the first cores 153 and the second cores 155. Profile 2 is obtained when current flows through the central core 151 and the second cores 155. Profile 3 is obtained when current flows through the central core 151 and the first cores 153.

By varying the magnetic field distribution, the magnetic field in the process chamber (e.g., process chamber 1308 in FIG. 16) may be varied, and this can vary the plasma density at different locations in the process chamber. Thus, different amount of material can be etched (or different amount of material can be deposited) in different locations on a wafer (e.g., wafer 90 in FIG. 16) in the process chamber.

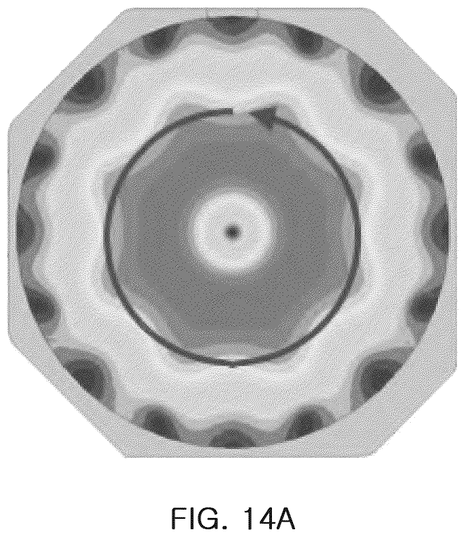

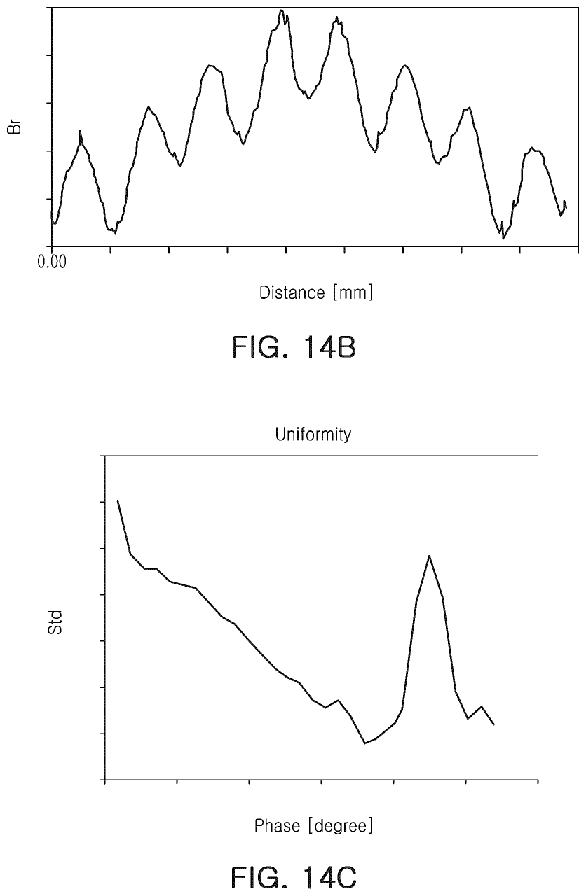

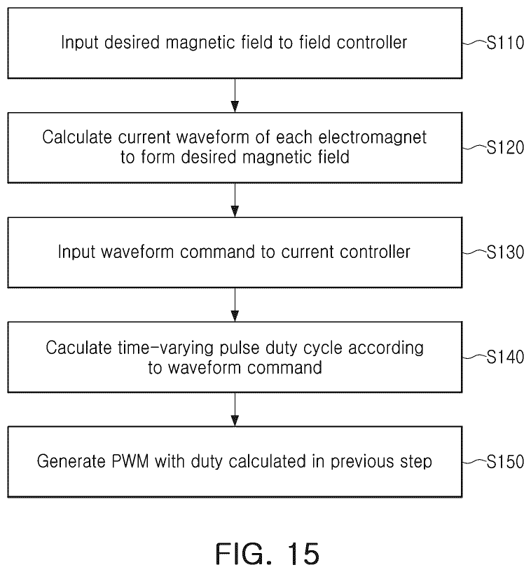

FIGS. 14A, 14B, and 14C illustrate uniformity in an azimuth direction according to a phase difference of each electromagnet (e.g., electromagnet array illustrated in FIGS. 15A-15B or 16A-16B) in a magnetic field generation device (e.g., magnetic field generation device 100 of FIG. 4), according to some example embodiments. As illustrated in FIG. 14C, uniformity in the azimuth direction is improved according to an optimal phase value.

FIG. 15 is a flowchart of an operation of a magnetic field generation device 100, according to some example embodiments. It is understood that additional operations can be provided before, during, and after the operations in FIG. 15, and some of the operations described below can be replaced or eliminated, for additional embodiments of the method. The order of the operations/processes may be interchangeable, or two or more operations can be performed simultaneously.

Referring to FIG. 15, with continued reference to FIGS. 4-14, in operation S110, the magnetic field controller 130 may input a target magnetic field distribution. In operation S120, the magnetic field controller 130 may calculate a current waveform of each electromagnet that matches the target magnetic field distribution. In operation S130, the magnetic field controller 130 may transmit a command corresponding to the calculated current waveform to the current controller 120. In operation S140, the current controller 120 may calculate a pulse duty cycle forming the current waveform. In operation S150, the current controller 120 may supply current to each electromagnet by generating PWM matching the pulse duty cycle. As a result, a time-varying magnetic field corresponding to the target magnetic field distribution may be formed in the electromagnet array.

The magnetic field generation device, according to some example embodiments, may generate a variety of magnetic field profiles (radial/azimuth directions) as compared to the electromagnets used in the existing etching facility. The magnetic field generation device, according to some example embodiments, also enables temporal control of the magnetic field profiles. While the magnetic field generation device, according to some example embodiments, is described with reference to an etching facility/process, it will be understood that the present disclosure is likewise applicable to other technology fields where it may be advantageous to have magnetic field control.

FIG. 16 illustrates a semiconductor wafer processing system for performing plasma etching on a semiconductor wafer, according to some example embodiments. The semiconductor wafer processing system will be described with respect to etching operations, but it will be understood that embodiments disclosed herein are also applicable to deposition operations. Referring to FIG. 16, the semiconductor wafer processing system includes a plasma etching device 1000 having a process chamber 1308 and an electrostatic chuck 1101 positioned in the process chamber 1308. The plasma etching device 1000 may perform etching of a wafer 90 that is secured using the electrostatic chuck 1101 in the process chamber 1308. The etching process may be performed using an inductively coupled plasma (ICP) generated by electromagnetic induction, for example using time-varying magnetic fields. The electrostatic chuck 1101 may also be used in an etching processing device that uses charge coupled plasma (CCP).

The semiconductor wafer processing system 1300 may be provided with an electrostatic chuck assembly 1400 including the electrostatic chuck 1101 for mounting the wafer 90, for example, a semiconductor wafer, in a central portion adjacent the base of a cylindrical process chamber 1308. The electrostatic chuck assembly 1400 may include the electrostatic chuck 1101, and a control unit 1200 for controlling an operation of the electrostatic chuck 1101.

The electrostatic chuck 1101 may include a base 1110 and a dielectric stack 1140 adhered to the base 1110 by an adhesive layer 1130. The dielectric stack 1140 may include a heater dielectric layer 1141 and an electrostatic dielectric layer 1142, sequentially stacked on the base 1110. The adhesive layer 1130 may have a double-layer structure including a first adhesive 1131 and a second adhesive 1132. A metal plate 1120 may be further provided between the first adhesive 1131 and the second adhesive 1132. The base 1110 may have a cylindrical or disk shape formed of metal, such as aluminum (Al), titanium (Ti), stainless steel, tungsten (W), or alloys thereof.

The inside of the process chamber 1308 in which the electrostatic chuck 1101 is installed may form a high temperature environment, and when the wafer 90 is exposed to high temperature plasma, the wafer 90 is bombarded with ions generated in the plasma. There may be a need to cool the wafer 90 to avoid damage to the wafer 90 and to ensure uniform plasma processing. To cool the wafer 90, the base 1110 may further be provided with a coolant channel 1112 through which coolant flows. For example, the coolant may include water, ethylene glycol, silicone oil, liquid Teflon, or a mixture of water and glycol. The coolant channel 1112 may have a concentric or helical pipe structure around a central axis of the base 1110. The coolant channel 1112 may be connected to a temperature controller 1230 of the control unit 1200. A flow rate and temperature of coolant circulating in the coolant channel 1112 may be controlled by the temperature controller 1230.

The base 1110 may be electrically connected to a bias power source 1220 of the control unit 1200. High frequency power (high frequency or radio frequency) may be applied to the base 1110 from the bias power source 1220, and thus the base 1110 may serve as an electrode for generating plasma. The base 1110 may further include a temperature sensor 1114. The temperature sensor 1114 may transmit the measured temperature of the base 1110 to a main controller 1250 of the control unit 1200. A temperature of the electrostatic chuck 1101, for example, a temperature of the electrostatic dielectric layer 1142 or the wafer 90, may be predicted based on the temperature measured from the temperature sensor 1114.

The heater dielectric layer 1141 may include an embedded heater electrode 1145. The heater dielectric layer 1141 may be or include a dielectric such as ceramic, such as aluminum oxide (Al₂O₃), aluminum nitride (AlN), or yttrium oxide (Y₂O₃), or resin, such as polyimide. The heater dielectric layer 1141 may be cylindrical or disk shaped.

The heater electrode 1145 may be formed of a conductor, such as a metal such as tungsten (W), copper (Cu), nickel (Ni), molybdenum (Mo), nickel-aluminum alloy (Ni—Al alloy), or a conductive ceramic such as tungsten carbide (WC), molybdenum carbide (MoC), titanium nitride (TiN), and the like. The heater electrode 1145 may be electrically connected to a heater power source 1240 of the control unit 1200. The heater electrode 1145 generates heat by power, for example, an alternating current voltage, from the heater power source 1240, so that a temperature of the wafer 90 may be adjusted. The heater electrode 1145 may have a concentric cylindrical or spiral pattern based on a central axis of the heater dielectric layer 1141.

An adsorption electrode 1155 may be embedded in the electrostatic dielectric layer 1142. The adsorption electrode 1155 may also be referred to as a clamp electrode. The electrostatic dielectric layer 1142 may be formed of a dielectric such as ceramic, such as aluminum oxide (Al₂O₃), aluminum nitride (AlN), or yttrium oxide (Y₂O₃), or resin, such as polyimide. The electrostatic dielectric layer 1142 may be cylindrical or disk shaped. The wafer 90 may be disposed on the electrostatic dielectric layer 1142. The adsorption electrode 1155 may be formed of a conductor, such as a metal such as tungsten (W), copper (Cu), nickel (Ni), molybdenum (Mo), nickel-aluminum alloy (Ni—Al alloy), or a conductive ceramic such as tungsten carbide (WC), molybdenum carbide (MoC), titanium nitride (TiN), and the like.

The adsorption electrode 1155 may be electrically connected to an electrostatic chuck power source (ESC power source) 1210 of the control unit 1200. An electrostatic force may be generated between the adsorption electrode 1155 and the wafer 90 by a power applied from the electrostatic chuck power source 1210, for example, a direct current voltage, so that the wafer 90 may be secured on the electrostatic dielectric layer 1142. The adsorption electrode 1155 may be composed of a plurality of sub-adsorption electrodes positioned to be spaced apart from each other within the electrostatic dielectric layer 1142, as illustrated in FIG. 16.

The dielectric stack 1140 may further include a heat distribution layer 1147 provided between the heater dielectric layer 1141 and the electrostatic dielectric layer 1142. The heat distribution layer 1147 may include, for example, an aluminum nitride layer (AlN), a boron nitride layer (BN), a tungsten layer (W), a molybdenum layer (Mo), and the like, having thermal conductivity of about 10 W/mK or more. The heat distribution layer 1147 may distribute heat generated from the heater electrode 1145 uniformly.

An electrostatic chuck power source 1210, bias power source 1220, heater power source 1240, and temperature controller 1230 may be controlled by a main controller 1250. For example, based on a temperature measured from the temperature sensor 1114, the main controller 1250 may measure temperatures of the electrostatic chuck 1101 to the wafer 90, and adjust a power of the heater power source 1240 to adjust an amount of heat generated from the heater electrode 1145. Accordingly, the temperatures of the electrostatic chuck 1101 to the wafer 90 may be appropriately controlled.

The electrostatic chuck 1101 may have a stepped structure suitable for applying a uniform electric field to the wafer 90. The electrostatic dielectric layer 1142 may be coupled to the heater dielectric layer 1141 without the aid of an adhesive layer. The heater dielectric layer 1141 may be coupled to the base 1110 using the adhesive layer 1130 having a double layer structure. The electrostatic chuck 1101 may be supported by a support portion 1116 fixed to an inner wall of the process chamber 1308. A baffle plate 1125 may be provided between the electrostatic chuck 1101 and the inner wall of the process chamber 1308. An exhaust pipe 1124 may be provided below the process chamber 1308, and the exhaust pipe 1124 may be connected to a vacuum pump 1126. A gate valve 1128 may be provided on an outer wall of the process chamber 1308 to open and close an opening 1127 used for loading and unloading the wafer 90.

A dielectric window 1152 spaced apart from the electrostatic chuck 101 may be provided on a ceiling of the process chamber 1308. An antenna chamber 1156 accommodating a high-frequency antenna 1154 in a spiral or concentric coil shape may be installed integrally with the process chamber 1308 in the dielectric window 1152. The high-frequency antenna 1154 may be electrically connected to a high-frequency power source 1157 for plasma generation through an impedance matcher 1158. The high-frequency power source 1157 may output high-frequency power suitable for plasma generation. The impedance matcher 1158 may be provided to match the impedance of the high-frequency power source 1157 and the impedance of the load, such as the high-frequency antenna 1154.

The gas supply source 1166 may supply processing gas, such as an etching gas, to the process chamber 1308 through a supply nozzle or porthole 1164 provided on a side wall of the process chamber 1308. To perform an etching process, a gate valve 1128 may be opened to load (or mount) the wafer 90 onto the electrostatic chuck 1101 within the process chamber 1308. The wafer 90 may be secured to the electrostatic chuck 1101 by electrostatic force generated when power is applied from the electrostatic chuck power source 1210 to the electrostatic chuck 1101. Etching gas may be introduced into the process chamber 1308 from a gas supply source 1166. In this case, the pressure within the process chamber 1308 may be set to a predetermined value using the vacuum pump 1126. Power may be applied from the high-frequency power source 1157 to the high-frequency antenna 1154 via an impedance matcher 1158. In addition, power may be applied to the base 1110 from the bias power source 1220.

The etching gas introduced into the process chamber 1308 may spread uniformly in a plasma processing chamber 1172 below the dielectric window 1152. A magnetic field may be generated around the high-frequency antenna 1154 by current flowing in the high-frequency antenna 1154, and a magnetic force line may penetrate the dielectric window 1152 and pass through the plasma processing chamber 1172. An induced electric field may be generated due to temporal changes in the magnetic field, and electrons accelerated by the induced electric field may collide with molecules or atoms of the etching gas, thereby generating plasma. For example, plasma may be formed by generating a time-varying magnetic field using a magnetic field generation device, as described in FIGS. 1 to 15. By supplying plasma ions to the wafer 90, wafer processing, for example, an etching operation, may be performed in the plasma process chamber 1172.

The magnetic field generation device 100 described above may be implemented with a hardware component, a software component, and/or a combination of a hardware component and a software component. For example, the device, method, and component described in the example embodiments may be implemented using one or more general-purpose computers and special purpose computers such as, processors, controllers, arithmetic logic units (ALUs), digital signal processors, microcomputers, field programmable gate arrays (FPGAs), programmable logic units (PLUS), microprocessors, or any other device capable of executing and responding to instructions. The processing device may execute an Operating System (OS) and one or more software applications running on the operating system. In addition, the processing device may also access, store, manipulate, process, and generate data in response to execution of the software. For convenience of understanding, it may be seen that, although one processing device is sometimes described as being used, one of ordinary skill in the art will recognize that the processing device may include a plurality of processing elements and/or a plurality of types of processing elements. For example, the processing device may include a plurality of processors or one processor and one controller. Other co-processor configurations are also possible, such as a Parallel Processor.

The software may include a computer program, code, instructions, or a combination of one or more thereof, and configure the processing device to operate as desired or command the processing device independently or collectively. The software and/or data may be permanently or temporarily embodied on any type of machine, component, physical device, virtual equipment, computer storage medium or device, or transmitted signal waves, to be interpreted by or provide instructions or data to the processing device. The software may be distributed over a computer system connected via a network, and stored or executed in a distributed manner. The software and data may be stored in one or more computer-readable recording media.

The time-varying rotating magnetic field generation device, according to some example embodiments, may include an electromagnet array configured for temporal control, a current controller capable of applying a desired current waveform, and a magnetic field controller calculating a current waveform of each electromagnet to form magnetic field distribution, and may be mounted on an upper portion of a showerhead. In some example embodiments, the electromagnet array may comprise each electromagnet with symmetry in an azimuth direction, and the electromagnets comprise a magnetic core, coil, and yoke. In some example embodiments, a magnetic yoke including iron and that increases magnetic flux density into a chamber (e.g., a process chamber) may be manufactured integrally with the magnetic core and may be located on a side (e.g., an upper portion) of the electromagnet array. In some example embodiments, an area of the electromagnet core may increase from an edge to a center to match a total amount of electromagnet flux. In some example embodiments, an electromagnet may be manufactured in a structure which allows 3 A current to be applied to maintain Ampere-Turn to enable time-varying control and reduce inductance by lowering the number of turns. In some example embodiments, compensation for changes in the magnetic field when applying the same current depending on a temperature environment is required, and this may be implemented through feedback control by a magnetic sensor.

In some example embodiments, the current controller may supply a current waveform to each electromagnet. In some example embodiments, an applied current waveform may be formed by temporal variation of pulse duty. In some example embodiments, the magnetic field controller may transmit a current waveform to form a time-varying rotating magnetic field to the current controller. In some example embodiments, local plasma density distribution control is possible by magnetic field distribution control based on a time average of the rotating magnetic field. In some example embodiments, discontinuity of the magnetic field due to a position of the electromagnet may be compensated for by control due to a change in phase of each electromagnet. In some example embodiments, the magnetic field generation device may be manufactured to be embedded inside a showerhead of the process chamber 1308, and may be mounted on an external portion, rather than in an upper portion of the facility. In some example embodiments, the magnetic field generation device is manufactured as an embedded type inside the showerhead of the process chamber 1308, so that an ampere turn required for the electromagnet may be reduced due to a decrease in a distance from a target point.

The magnetic field generation device, according to some example embodiments, is manufactured such that it that may be mounted on the outside of the wafer processing facility, so that a height of plasma distribution may be controlled. In some example embodiments, a magnetic field generation device may control magnetic field distribution using an electromagnet, and enable azimuth direction and local distribution control. In example embodiments, local distribution may be controlled and uniformity in the azimuth direction may be secured due to temporal control and control by the phase difference of each electromagnet. Example embodiments enable various plasma distribution control therethrough.

As set forth above, a magnetic field generation device and an operating method thereof, according to some example embodiments, may generate a time-varying rotating magnetic field by controlling a temporal current waveform of each electromagnet array, and thereby control etching uniformity in radial and azimuth directions, and provide temporal distribution control.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

1. A magnetic field generation device, comprising:
an array of electromagnets including a plurality of electromagnets;
a current controller configured to generate a plurality of current waveforms and configured to apply each current waveform to a respective one of the plurality of electromagnets, the current controller further configured to control a pulse duty cycle of each of the plurality of current waveforms; and
a magnetic field controller configured to calculate each of the plurality of current waveforms to be provided to the respective one of the plurality of electromagnets to generate a desired magnetic field distribution.

2. The magnetic field generation device of claim 1, wherein the plurality of electromagnets include a central electromagnet, and peripheral electromagnets having symmetry in an azimuth direction and arranged about the central electromagnet,
wherein each electromagnet of the plurality of electromagnets includes a magnetic core and a coil, and the plurality of electromagnets are magnetically coupled to each other via a yoke.

3. The magnetic field generation device of claim 2, wherein the yoke is integrally implemented with the magnetic cores of the plurality of electromagnets.

4. The magnetic field generation device of claim 2, wherein a cross-sectional area of a core of the central electromagnet is larger than respective cross-sectional areas of the cores of each of the peripheral electromagnets.

5. The magnetic field generation device of claim 1, wherein each of the plurality of electromagnets is configured to apply a 3 A current with time-varying control.

6. The magnetic field generation device of claim 1, further comprising:
at least one magnetic sensor configured to sense a magnetic field generated by the magnetic field generation device,
wherein the magnetic field controller is configured to calculate one or more of the plurality of current waveforms according to a change in the sensed magnetic field.

7. The magnetic field generation device of claim 1, wherein the current controller is configured to apply each of the plurality of current waveforms to the respective one of the plurality of electromagnets using temporal variation of pulse duty.

8. The magnetic field generation device of claim 1, wherein the magnetic field controller is configured to calculate each of the plurality of current waveforms to generate a time-varying rotating magnetic field, and
wherein the magnetic field controller is further configured to control the desired magnetic field distribution based on a time average of the time-varying rotating magnetic field.

9. The magnetic field generation device of claim 1, wherein the magnetic field generation device is mounted on an upper portion of a showerhead of a process chamber of a wafer processing device.

10. The magnetic field generation device of claim 1, wherein the magnetic field generation device is of an embedded type and positioned inside a showerhead of a process chamber of a wafer processing device.

11. A magnetic field generation device, comprising:
a cylindrical yoke;
a plurality of magnetic cores on the cylindrical yoke; and
a plurality of coils, wherein
each of the plurality of coils are wound around a respective one of the plurality of magnetic cores, and
each of the plurality of coils is configured to generate a time-varying rotating magnetic field in response to an applied current waveform.

12. The magnetic field generation device of claim 11, wherein the magnetic field generation device is mounted on a showerhead of a process chamber of a wafer processing device, embedded in the showerhead, or mounted on a sidewall of the process chamber.

13. The magnetic field generation device of claim 11, wherein the plurality of magnetic cores comprises:
a central core;
first cores surrounding the central core; and
second cores surrounding the first cores,
wherein the first cores and the second cores have symmetry in an azimuth direction.

14. The magnetic field generation device of claim 13, wherein a cross-sectional area of the central core is larger than a cross-sectional area of each of the first cores, and
the cross-sectional area of each of the first cores is larger than a cross-sectional area of each of the second cores.

15. The magnetic field generation device of claim 11, further comprising:
a current controller configured to generate a plurality of current waveforms and configured to apply each current waveform to a respective one of the plurality of coils by calculating a variable pulse duty cycle according to a current waveform command; and
a magnetic field controller configured to calculate each of the plurality of current waveforms to generate a desired magnetic field distribution.

16. A magnetic field generation device, comprising:
an electromagnet device having a plurality of electromagnets; and
a magnetic field sensor layer having a plurality of magnetic sensors, each magnetic sensor corresponding to a position of an electromagnet of the plurality of electromagnets.

17. The magnetic field generation device of claim 16, wherein the electromagnet device comprises an electromagnet array that includes the plurality of electromagnets, and the magnetic field generation device further comprises:
a current controller configured to generate a plurality of current waveforms and configured to apply each current waveform to a respective one of the plurality of electromagnets; and
a magnetic field controller configured to calculate each of the plurality of current waveforms to obtain a desired magnetic field distribution.

18. The magnetic field generation device of claim 17, wherein the plurality of electromagnets have symmetry in an azimuth direction.

19. The magnetic field generation device of claim 17, wherein the electromagnet array includes a plurality of cores and a yoke integrally implemented with the plurality of cores.

20. The magnetic field generation device of claim 16, wherein each of the plurality of magnetic sensors is configured to measure a magnetic field of about 3000 G.

21-25. (canceled)
